(19) United States
(12) Patent Application Publication
(10) Pub. No.: US 2026/0072111 A1
(43) Pub. Date: Mar. 12, 2026

(54) METHODS AND SYSTEMS FOR MAGNETIC RESONANCE IMAGING

(71) Applicant: UNITED IMAGING HEALTHCARE NORTH AMERICA, INC., Houston, TX (US)

(72) Inventors: Hongyu LI, Houston, TX (US); Yongquan YE, Houston, TX (US); Junpu HU, Shanghai (CN); Qi LIU, Houston, TX (US); Jian XU, Houston, TX (US)

(73) Assignee: UNITED IMAGING HEALTHCARE NORTH AMERICA, INC., Houston, TX (US)

(21) Appl. No.: 18/829,251

(22) Filed: Sep. 9, 2024

(51) Int. Cl. G01R 33/56; G01R 33/54

(52) U.S. Cl. CPC G01R 33/5608; G01R 33/543

(57) ABSTRACT

Embodiments of the present disclosure provides a method implemented on a computing device including at least one processor and a storage device. The method, may include obtaining magnetic resonance (MR) images of a subject, at least two of the MR images being acquired by an MRI scanner according to different imaging parameters. The method may also include obtaining one or more target MR mappings corresponding to at least a portion of the MR images by processing the MR images through a trained machine learning model. The second count of the target MR mappings may be less than a first count of the MR images. The trained machine learning model may include at least two sub-models, and each sub-model processes at least one of the MR images.

### TECHNICAL FIELD

The present disclosure relates to the field of magnetic resonance imaging, in particular to methods and systems for magnetic resonance imaging based on a machine learning technique.

### BACKGROUND

In magnetic resonance imaging (MRI), T1 mapping provides information about the longitudinal relaxation time of tissues, which is crucial for distinguishing between healthy and diseased tissues. T2 mapping measures the transverse relaxation time, offering insights into tissue hydration and edema. T1rho (T1ρ) mapping, on the other hand, focuses on the interaction between water molecules and macromolecules, providing additional biochemical environment information. However, existing T1, T2, and T1rho mapping techniques suffer from long scan times and motion artifacts due to these extended durations. Furthermore, these mappings require separate scans to be performed individually, further increasing the overall scan time and adding to patient discomfort. Especially in cardiac scans, breath-holding is required, which further complicates the scanning process.

Therefore, there is an urgent need for a method that can reduce scan time or quickly obtain mapping images.

### SUMMARY

One or more embodiments of the present disclosure provide a method implemented on a computing device including at least one processor and a storage device, the method, comprising: obtaining magnetic resonance (MR) images of a subject, each of the MR images being acquired by an MRI scanner according to a target imaging parameter, at least two of the MR images corresponding to different target imaging parameters; obtaining one or more target MR mappings corresponding to at least a portion of the MR images by processing the MR images through a trained machine learning model, a second count of the target mappings being less than a first count of the MR images; wherein the trained machine learning model may include at least two sub-models, and each sub-model processes at least one of the MR images.

In some embodiments, the obtaining one or more target MR mappings corresponding to at least a portion of the MR images by processing the MR images through a trained machine learning model may include: obtaining a relaxation time corresponding to at least one of the MR images; and obtaining the one or more target MR mappings by processing the MR images and the relaxation time corresponding to the at least one of the MR images through the trained machine learning model.

In some embodiments, the first count may be determined based on the second count.

In some embodiments, the method may further comprise determining the second count based on one or more target quantitative parameters of the subject, the one or more target quantitative parameters including at least one of T1 mapping, T2 mapping, or T1rho mapping.

In some embodiments, the MR images may include at least one MR image, a type of the target imaging parameter corresponding to the at least one MR image being the same as a type of one of the one or more target quantitative parameters.

In some embodiments, one of the sub-models may include at least one of a fully connected (FC) network, a convolutional neural network (CNN), a recurrent neural network (RNN), or a Transformer.

In some embodiments, the trained machine learning model may be obtained through operations including: obtaining multiple training samples, wherein each training sample of the multiple training samples includes sample MR images and a reference mapping; performing multiple iterations on a preliminary machine learning model based on the multiple training samples to obtain the trained machine learning model; the preliminary machine learning model including at least two sub-models; wherein, at least one iteration of the multiple iteration includes: obtaining a predicted mapping by inputting the sample MR images into the preliminary machine learning model;

determining a value of a target loss function based on the predicted mapping and the reference mapping; and updating network parameters of the at least two sub-models based on the value of the target loss function.

In some embodiments, the target loss function may include at least two loss terms, and each loss term corresponds to a sub-model.

In some embodiments, at least one of the at least two loss terms may include a weighting factor, the weighting factor being updated when updating network parameters of the at least two sub-models.

In some embodiments, the method may further comprise updating the network parameters of the at least two sub-models and the weighting factor based on the value of the target loss function.

In some embodiments, the obtaining the one or more target mappings corresponding to at least a portion of the MR images by processing of the MR images through a trained machine learning network may include: obtaining a first MR mapping corresponding to a target quantitative parameter by processing a first portion of the MR images through a first sub-model; obtaining a second MR mapping corresponding to the target quantitative parameter by processing a second portion of the MR images through a second sub-model; wherein the third count and the fourth count are less than or equal to the first count; based on weight parameters of the first sub-model and the second sub-model, obtaining a target MR mapping corresponding to the target quantitative parameter by weighting the first MR mapping and the second MR mapping.

In some embodiments, the first count may be equal to 2, and the MR may include a first MR image corresponding to a first target imaging parameter and a second MR image corresponding to a second target imaging parameter that is different from the first target imaging parameter, the one or more target MR mappings corresponding to a target quantitative parameter that is same as the first target imaging parameter or the second target imaging parameter.

One or more embodiments of the present disclosure provide a system for magnetic resonance imaging, comprising: an acquisition module configured to obtain MR images of a subject, each of the MR images being acquired by an MRI scanner according to a target imaging parameter, at least two of the MR images corresponding to different target imaging parameters; a processing module configured to obtain target MR mappings corresponding to at least a portion of the MR images by processing the MR images through a trained machine learning network, a second count of the target MR mappings being less than ta first count of the MR images; wherein, the trained machine learning network includes at least two sub-models, and each sub-model processes at least one of the MR images.

One or more embodiments of the present disclosure provide a device for magnetic resonance imaging comprising a processor, wherein the processor is used to execute any of the methods for magnetic resonance imaging described above.

### BRIEF DESCRIPTION OF THE DRAWINGS

This description will be further explained in the form of exemplary embodiments, which will be described in detail by means of accompanying drawings. These embodiments are not restrictive, in which the same numbering indicates the same structure, wherein:

FIG. 1 is a schematic diagram illustrating an exemplary application scenario of a system for magnetic resonance (MR) imaging according to some embodiments of the present disclosure;

FIG. 2 is an exemplary flowchart illustrating a process for MR imaging according to some embodiments of the present disclosure;

FIG. 3 is an exemplary schematic diagram illustrating the acquisition of an MR mapping according to other embodiments of the present disclosure;

FIG. 4 is an exemplary schematic diagram illustrating the acquisition of a specific type of MR mapping according to some embodiments of the present disclosure;

FIG. 5 is an exemplary schematic diagram illustrating the acquisition of multiple types of MR mappings according to some embodiments of the present disclosure;

FIG. 6 is an exemplary flowchart illustrating process for training a trained machine learning model according to some embodiments of the present disclosure; and

FIG. 7 is an exemplary block diagram illustrating system for MR imaging according to some embodiments of the present disclosure.

### DETAILED DESCRIPTION

The technical schemes of embodiments of the present disclosure will be more clearly described below, and the accompanying drawings need to be configured in the description of the embodiments will be briefly described below. Obviously, the drawings in the following description are merely some examples or embodiments of the present disclosure, and will be applied to other similar scenarios according to these accompanying drawings without paying creative labor. Unless obviously obtained from the context or the context illustrates otherwise, the same numeral in the drawings refers to the same structure or operation.

It should be understood that the terms “system”, “device”, “unit”, and/or “module” used in this document are methods used to distinguish different components, elements, parts, sections, or assemblies at different levels. However, if other terms can achieve the same purpose, they can be substituted for these terms.

As indicated in the present disclosure and the claims, unless the context clearly suggests exceptions, the words “a”, “an”, “one”, and/or “the” do not specifically refer to the singular and may also include the plural. Generally, the terms “including” and “comprising” only indicate the inclusion of clearly identified steps and elements, which do not constitute an exclusive list. Methods or devices may also include other steps or elements.

Flowcharts are used in the present disclosure to illustrate the operations performed by the system according to the embodiments of the present disclosure. It should be understood that the preceding or subsequent operations are not necessarily executed in precise order. Instead, the steps can be processed in reverse order or simultaneously. Meanwhile, other operations can be added to these processes, or one or more steps can be removed from these processes.

Currently, in related technologies, fully connected networks (FC) are commonly used for parameter mapping of weighted images obtained from magnetic resonance scans. However, reconstructing weighted images and achieving high-precision mapping imaging using fully connected networks still faces challenges, especially in terms of robustness to noise and motion interference. Additionally, in related techniques, when obtaining mapping images (also referred to as MR mappings, e.g., T1 mapping), at least three images are required during an inversion recovery process. When the number of images is insufficient, it may result in the inability to obtain the corresponding mapping images. However, as the number of images increases, it inevitably leads to an increase in scanning time, thereby decreasing the imaging efficiency.

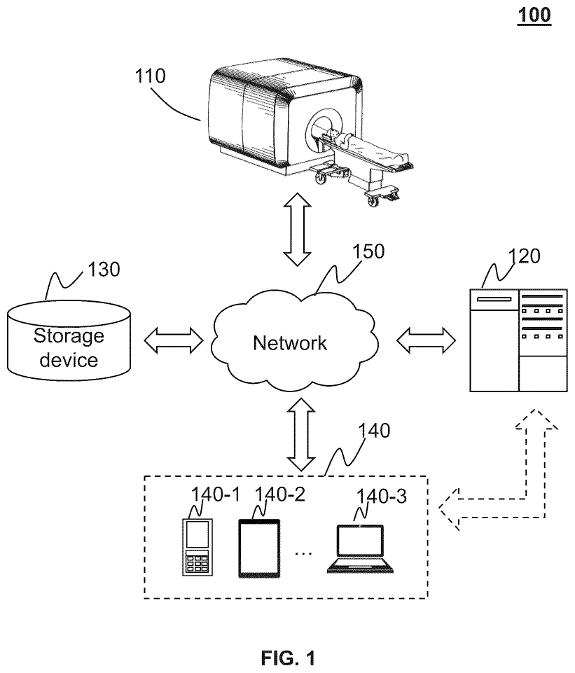

FIG. 1 is a schematic diagram illustrating an exemplary application scenario of a system for magnetic resonance imaging (MRI) according to some embodiments of the present disclosure.

As shown in FIG. 1, the system for MRI (also referred to as MRI system) 100 may include a magnetic resonance imaging (MRI) scanner 110, a processing device 120, a storage device 130, one or more terminals 140, and a network 150. In some embodiments, the MRI scanner 110, the processing device 120, the storage device 130, and/or the one or more terminals 140 may be connected and/or communicate with each other through wireless connections, wired connections, or combinations of both. The connections between components in the MRI system 100 may be variable. For example, the MRI scanner 110 may be connected to the processing device 120 through the network 150. As another example, the MRI scanner 110 may be directly connected to the processing device 120.

In some embodiments, the MRI system 100 may include a single-modality imaging system and/or a multi-modality imaging system. The single-modality imaging system may include, for example, a system for MR imaging. The multi-modality imaging system may include, for example, a system for X-ray imaging-magnetic resonance imaging (X-ray-MRI), a system for single photon emission computed tomography-MRI (SPECT-MRI), a system for digital subtraction angiography-MRI (DSA-MRI), a system for MRI-computed tomography (MRI-CT), a system for positron emission tomography-MRI (PET-MRI), etc.

The MRI scanner 110 may be configured to scan a subject (or a part of the subject) to obtain image data of the subject, such as an MR weighted image. In some embodiments, the MRI scanner 110 may include, for example, a main magnet, gradient coils (also known as spatial encoding coils), radiofrequency (RF) coils, etc. The subject scanned by the MRI scanner 110 may be biological or non-biological. For example, the subject may include a patient, an artificial object, etc. As another example, the subject may include a specific part, an organ, a tissue, and/or a physical point of a patient. By way of example only, the subject may include the head, the brain, the neck, a body, a shoulder, an arm, the chest, the heart, the stomach, blood vessels, soft tissues, a knee joint, a foot, etc., or combinations of them.

The processing device 120 may be configured to process data and/or information obtained from the MRI scanner 110, the storage device 130, and/or the one or more terminals 140. For example, the processing device 120 may obtain MR images of a subject each of which is acquired by an MRI scanner according to a target imaging parameter. At least two of the MR images may correspond to different target imaging parameters. The processing device 120 may obtain one or more target MR mappings corresponding to at least a portion of the MR images by processing the MR images through a trained machine learning model. A second count of the target mappings may be less than a first count of the MR images. In some embodiments, the processing device 120 may be a single server or a group of servers. The server group may be centralized or distributed. In some embodiments, the processing device 120 may access information and/or data from the MRI scanner 110, the storage device 130, and/or the one or more terminals 140 via the network 150. As another example, the processing device 120 may be directly connected to the MRI scanner 110, the one or more terminals 140, and/or the storage device 130 to access information and/or data. In some embodiments, the processing device 120 may be implemented on a cloud platform. For example, the cloud platform may include a private cloud, a public cloud, a hybrid cloud, a community cloud, a distributed cloud, inter-cloud, multi-cloud, etc., or combinations of them.

The storage device 130 may store data, instructions, and/or any other information. In some embodiments, the storage device 130 may store data obtained from the MRI scanner 110, the processing device 120, and/or the one or more terminals 140. In some embodiments, the storage device 130 may store data and/or instructions, which the processing device 120 may execute or use to execute the exemplary methods described in the present disclosure. In some embodiments, the storage device 130 may include a mass storage device, a removable storage device, a volatile read-write memory, a read-only memory (ROM), etc., or combinations of them. In some embodiments, the storage device 130 may be implemented on a cloud platform, as described elsewhere in the present disclosure.

In some embodiments, the storage device 130 may be connected to the network 150 to communicate with one or more other components in the MRI system 100 (e.g., the MRI scanner 110, the processing device 120, and/or the one or more terminals 140). One or more components of the MRI system 100 may access data or instructions stored in the storage device 130 via the network 150. In some embodiments, the storage device 130 may be part of the processing device 120 or the one or more terminals 140.

At least one of the one or more terminals 140 may be configured to enable interaction between a user and the MRI system 100. For example, the at least one of the one or more terminals 140 may receive an instruction from the user to scan a target using the MRI scanner 110. As another example, the at least one of the one or more terminals 140 may receive a processing result (e.g., a mapping image of the subject) from the processing device 120 and display the processing result to the user. In some embodiments, the at least one of the one or more terminals 140 may connect and/or communicate with the MRI scanner 110, the processing device 120, and/or the storage device 130. In some embodiments, the at least one of the one or more terminals 140 may include a mobile device 140-1, a tablet computer 140-2, a laptop computer 140-3, or combinations of these. In some embodiments, the at least one of the one or more terminals 140 may be part of the processing device 120 or the MRI scanner 110.

The network 150 may include any suitable network that facilitates the exchange of information and/or data for the MRI system 100. In some embodiments, one or more components of the MRI system 100 (e.g., the MRI scanner 110, the processing device 120, the storage device 130, the terminal 140, etc.) may transmit information and/or data to one or more other components of the MRI system 100 via the network. For example, the processing device 120 may obtain image data (e.g., the MR images) from the MRI scanner 110 via the network 150. As another example, the processing device 120 may obtain the user instruction from the at least one of the one or more terminals via the network 150. In some embodiments, the network 150 may include one or more network access points. For example, the network 150 may include wired and/or wireless network access points, such as base stations and/or internet exchange points, through which one or more components of the MRI system 100 may connect to the network 150 to exchange data and/or information.

The above description is intended to be illustrative and not limiting of the scope of the present disclosure. Many alternatives, modifications, and variations will be apparent to those skilled in the art. The features, structures, methods, and characteristics of the exemplary embodiments described herein can be combined in various ways to obtain additional and/or alternative exemplary embodiments. In some embodiments, the MRI system 100 may include one or more additional components, and one or more of the above-mentioned components may be omitted. Additionally or alternatively, two or more components of the MRI system 100 may be integrated into a single component. For example, the processing device 120 may be integrated into the MRI scanner 110. As another example, components of the MRI system 100 may be replaced by other components that may perform the functions of the components. In some embodiments, the storage device 130 may be a data storage including a cloud computing platform, such as a public cloud, a private cloud, a community cloud, a hybrid cloud, etc. However, these variations and modifications do not depart from the scope of the present disclosure.

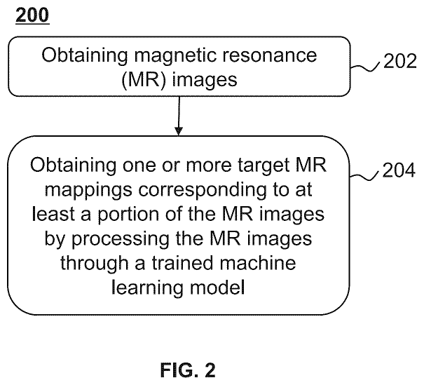

FIG. 2 is an exemplary flowchart illustrating a process for magnetic resonance imaging according to some embodiments of the present disclosure. In some embodiments, process 200 may be executed by a system for MR imaging (e.g., the MRI system 100) or a processing device (e.g., the processing device 120). As shown in FIG. 2, process 200 includes the following steps.

In 202, magnetic resonance (MR) images may be obtained.

The MR images may be acquired by an MRI scanner via scanning a subject according to an MR imaging technique. The MR imaging technique may be a multi-parameter imaging technique. In other words, each of the MR images may be acquired by the MRI scanner according to multiple imaging parameters. For example, the multiple imaging parameters may include an echo time, a repetition time, an inversion time, an inversion angle, etc.

In some embodiments, the MR images may be generated in one single MRI scan and may be used to simultaneously generate one or more types of target MR mappings (e.g., T1, T2, and T1rho mappings). As used herein, one single MRI scan refers to a completed MRI scan performed by an MRI scanner between when the MRI scanner is turned on and off.

In some embodiments, MR data (e.g., MR images) generated in one single MRI scan may be used to simultaneously generate T1, T2, and T1rho mappings.

In some embodiments, the MR imaging technique may include an MR weighted-imaging technique, an inversion recovery sequence imaging, a rapid imaging, etc. For example, the MR weighted-imaging technique may include a T1-weighted imaging technique, a T2-weighted imaging technique, a T2*-weighted imaging technique, an R*-weighted imaging technique, a T1rho-weighted imaging technique, etc. In some embodiments, each two of the MR images may be obtained using different MR imaging techniques. In some embodiments, at least two of the MR images may be obtained using the same MR imaging technique. For example, each two of the MR images may be a T1-weighted image and a T2-weighted image, or both may be T1-weighted images.

In some embodiments, each of the multiple MR images may correspond to a target imaging parameter associated with the subject. An MR image may represent a relationship of values of the target imaging parameter between different portions of the subject via the pixel values in the MR image. In other words, an MR image corresponding to a target imaging parameter may provide qualitative information of the target imaging parameter of different portions of the subject. The target imaging parameter may be used to denote a characteristic of different portions of the subject. The type of the target imaging parameter may include T1, T2, T2*, T1rho, R*, etc. In some embodiments, each of the multiple MR images may correspond to different types of target imaging parameters. In some embodiments, the multiple MR images may correspond to the same type of target imaging parameter. In some embodiments, at least two of the multiple MR images may correspond to different types of target imaging parameters. The target imaging parameter may be determined by a user according to actual clinical requirements, such as according to the type of the subject, a lesion in the subject, etc. The MR imaging technique and/or imaging parameters for acquiring an MR image may be determined based on the target imaging parameter corresponding to an MR image.

The MR images obtained using different weighted-imaging techniques may include different image types. In some embodiments, an image type of an MR image acquired by an MR imaging technique may be defined by a target imaging parameter (also referred to as an imaging target) that the MR image may mainly present via pixel values in the image. In some embodiments, an image type of an image acquired by an MR imaging technique may be defined by the type of the MR imaging technique.

In some embodiments, two of the MR images may be acquired according to different imaging parameters. For example, the MR images may be acquired by the same MR imaging technique (e.g., the T1-weighted imaging technique, the T2-weighted imaging technique, the T2*-weighted imaging technique, the R*-weighted imaging technique) according to different imaging parameters. As another example, the MR images may be acquired by the same MR imaging technique according to different MR pulse sequences. As still another example, each two of the MR images may be acquired by different MR imaging techniques. As still another example, at least two of the MR images may be acquired by the same MR imaging techniques. As still another example, at least two of the MR images may be acquired by the different MR imaging techniques (e.g., the T1-weighted imaging technique and the T2-weighted imaging technique).

For example, the MR images may include a T1-weighted image obtained using the T1-weighted imaging technique, the target imaging parameter may include T1, and the pixel values of the T1-weighted image may mainly represent distributions or difference of T1 of different portions of the subject. As another example, the MR images may include a T2-weighted image obtained using the T1-weighted imaging technique, a T2*-weighted image obtained using the T2-weighted imaging technique, an R*-weighted image obtained using the R*-weighted imaging technique, a T1rho-weighted image obtained using the T1rho-weighted imaging technique, or the like, or a combination thereof.

As a further example, for the T1-weighted image acquired by the T1-weighted imaging technique, the image grayscale may be primarily determined by T1, the MR image may be called a T1-weighted image. If the image grayscale is primarily determined by T2, the MR image may be called a T2-weighted image. Therefore, the “weighting” in a weighted image may refer to a specific target imaging parameter of the image, such as T1, T2, or T1rho. For different MR images, values of at least a portion of the multiple imaging parameters may be different. The imaging parameters for acquiring an MR image may be arranged in a time sequence to obtain an MR pulse sequence. The MR image may be acquired by the MRI scanner via applying the MR pulse sequence. For example, MR data obtained through a single scan. By setting different imaging parameters, different imaging targets may be obtained via the different MR pulse sequences. For example, the pulse sequence for acquiring a T1-weighted image may include a spin echo (SE) sequence, a fast spin echo (FSE) or rapid spin echo (RSE) sequence, a gradient echo (GRE) sequence, an inversion recovery (IR) sequence, etc. The pulse sequences for T2-weighted imaging may include a spin echo (SE) sequence, a fast spin echo (FSE) or rapid spin echo (RSE) sequence, a gradient echo (GRE) sequence, a double echo sequence, an inversion recovery (IR) sequence, etc.

In some embodiments, the first count may be at least 2.

A specific value of the first count may be directly specified by a user, for example, based on an imaging target, or may be determined through other methods. For example, the first count may be determined based on a second count or based on an image feature of one of the MR images. For example, the first count may be determined based on the acquired T1-weighted image, the T2-weighted image, the T1rho-weighted image, etc. The image feature of an MR image may include an image sharpness, a contrast, a signal-to-noise ratio, etc. More descriptions for the second count may be found elsewhere in the present disclosure.

Illustratively, the first count equals the second count plus n, where n is a positive integer greater than 1, and the second count is a positive integer greater than 1. Therefore, the first count may be 2, 3, 4, 6, 9, 10, etc. In some embodiments, the first count may be equal to the second count*n. For example, C1=C2+n, where C1 is the first count, and C2 is the second count.

In some embodiments, the value of n may be any specified value or determined based on a quality parameter. The quality parameters may include an image resolution, a signal-to-noise ratio, a sharpness, etc. For example, taking resolution as an example, when the resolution of one of the MR images is higher, the value of n may be larger. It can be understood that a higher resolution indicates more information in the MR image, and using a larger value of n (to include more input information) may obtain a higher-quality image.

Associating the first count with the second count allows precise control over the required first count, achieving the goal of not increasing additional scanning time and not reducing prediction effectiveness.

A correspondence between imaging parameters and the value of n may be pre-established and stored, and the processing device may obtain the value of n corresponding to the imaging parameters by looking up a relationship table. The imaging parameters here refer to those corresponding to all previously acquired MR images, where different MR images may have different corresponding n values for their imaging parameters.

In some embodiments, the processing device may construct a vector database (also referred to as a first vector database) based on imaging parameters and corresponding n values. The first vector database may include reference vectors and corresponding reference n values. The reference vectors may be obtained by vector transformation of the imaging parameters. Due to the large amount of imaging parameter data, converting the imaging parameters into the reference vectors may effectively improve the efficiency of querying the n value corresponding to the imaging parameters. During querying, the processing device may construct a target feature vector based on the current imaging parameters (for example, through vector transformation or feature extraction methods); and match at least one reference vector satisfying a preset condition in the vector database based on the target feature vector, where the preset condition may be that a vector distance is less than a distance threshold, and the vector distance may be Euclidean distance, cosine distance, etc.; and determine the target n value based on the n values corresponding to the reference vectors satisfying the preset condition. The target n value may be any one of the queried n values or the average value of the queried n values, which is not limited in this embodiment.

In some embodiments, the value of n may be determined through a trained machine learning model, also referred to as a first trained machine learning model, such as a convolutional neural network, a recurrent neural network, or a long short-term memory network.

Input data of the first trained machine learning model may be imaging parameters, and output data may be the predicted n value.

The first trained machine learning model may be trained based on a training dataset. The training dataset may include sample image data collected under different sample imaging parameters by an MRI scanner. In some embodiments, the sample imaging parameters of the sample image data may be determined from the sample image data as training samples. The labels (true or reference n values) may be assigned to each sample image data based on actual imaging effects or experience.

For example, five different n-value evaluation network configurations (Config1, Config2, . . . , Config5) may be defined, each with a different n value. Then, these five configurations may be configured to process the same imaging parameter set A, and the image quality evaluation metrics (such as sharpness scores of 80, 85, 90, 75, 82) are calculated for each configuration. By comparing the evaluation results, if Config3 (with a sharpness score of 90) performs best on all metrics, the n value of Config3 may be used as the label for imaging parameter set A.

In some embodiments, the training of the first trained machine learning model may be carried out in various ways. For example, after obtaining the training dataset, multiple iterations may be performed on the first trained machine learning model to be trained using the training dataset. At least one iteration may include selecting one or more training samples from the training dataset, inputting the one or more samples into a first preliminary machine learning model to be trained, and obtaining the predicted output of the first preliminary machine learning model corresponding to the one or more samples; determining a value of a loss function based on the predicted output of the first preliminary machine learning model corresponding to the one or more training samples and the labels corresponding to the one or more training samples; and updating the model parameters in the first preliminary machine learning model to be trained based on the value of the loss function. For example, the model parameters may be updated based on the gradient descent algorithm. When a termination condition is met (e.g., the loss function value converges, a count of iterations reaches a preset count, etc.), the iteration is terminated, and the first preliminary machine learning model is obtained.

In some embodiments, the n value may be determined based on the image feature of the MR image. For example, by establishing a correspondence between the image features and the n value, through a vector database (also referred to as a second vector database), or through a trained machine learning model (also referred to as a second trained machine learning model).

For example, the second vector database may include second reference vectors (obtained through vector transformation of imaging parameters) and their corresponding reference n values. The second trained machine learning model may be a deep learning model, such as a convolutional neural network (CNN) combined with a recurrent neural network (RNN) or a long short-term memory network (LSTM). An input of the second trained machine learning model includes imaging parameters, and an output is the n value. The second trained machine learning model may be trained based on second historical data, which includes MR images under different imaging parameters and their corresponding n values (labels). These labels may be obtained through manual annotation or other methods.

For more information about the vector database and the model determination, please refer to the relevant descriptions above on determining the imaging parameters and the n value. In specific implementations, replace imaging parameters with image features. Further details are not repeated here.

In some embodiments, the processing device may obtain the MR images by controlling an MRI scanner to scan the subject, or by retrieving them from a storage device or a database.

In 204, one or more target MR mappings corresponding to at least a portion of the MR images may be generated by processing the MR images through a trained machine learning model.

A target MR mapping may represent values of a target quantitative parameter of different portions of the subject. The target quantitative parameter may include T1, T2, T1rho, R*, etc. A target MR mapping corresponding to an MR image refers to that the type of the target quantitative parameter is same as the type of the target imaging parameter of the MR image. In other words, a target MR mapping corresponding to an MR image may provide quantitative information of a target imaging parameter of different portions of the subject represented in the MR image. In some embodiments, an MR mapping may be presented as an image, and the MR mapping may also be referred to be as an MR mapping image.

The one or more MR mappings may include a T1 mapping, a T2 mapping, a T1rho mapping, or the like, or a combination thereof. Different MR mappings may provide corresponding information of different quantitative parameters. For example, the T1 mapping may provide information of the longitudinal relaxation time of different portions (e.g., tissue) of the subject, which is crucial for distinguishing healthy tissues from diseased tissues; the T2 mapping may provide information of the transverse relaxation time different portions (e.g., tissue) of the subject and may provide insights into tissue hydration and edema; the T1rho mapping may provide information of the spin-lattice relaxation time different portions (e.g., tissue) of the subject and focus on the interaction between water molecules and macromolecules, providing additional biochemical environmental information.

The trained machine learning model refers to a composite network composed of two or more sub-models that may independently achieve corresponding functions. The sub-models within the trained machine learning model may independently predict an MR mapping based on input data without relying on other networks.

In some embodiments, each sub-model may be a machine learning model, such as a fully connected (FC) network, a convolutional neural network (CNN), a recurrent neural network (RNN), a Transformer, or any combination thereof. That is to say, each sub-model may be a separate network or a composite network. For example, assuming the trained machine learning model includes a first sub-model and a second sub-model, the first sub-model may be a fully connected network, and the second sub-model may be a CNN. Alternatively, the first sub-model may be a combination of the FC network and the CNN, while the second sub-model may be an RNN.

In some embodiments, each sub-model of the trained machine learning model may process at least one of the MR images. For example, the processing device may input the first count of the MR images into the trained machine learning model, and each sub-model in the trained machine learning model may process the first count of MR images. As another example, the first count of MR images may be divided into a first portion and a second portion, and at least one of the at least two sub-models may process MR images in the first portion, and the remaining sub-models may process the MR images in the second portion.

In some embodiments, the count of sub-models in the trained machine learning model may be determined based on imaging parameters or image features of MR images. Furthermore, the count of sub-models may be determined based on a vector database (also referred to as a third vector database) or a machine learning model (also referred to a third trained machine learning model). The specific determination method may be found in the description of the relationship between imaging parameters and the value of n above, which is not be repeated here.

For example, the third vector database may include third reference vectors (obtained through vector transformation of imaging parameters and/or image features) and a count of sub-models corresponding to these third reference vectors. The third trained machine learning model may be a deep learning model, such as a Convolutional Neural Network (CNN) combined with a Recurrent Neural Network (RNN) or a Long Short-Term Memory Network (LSTM). An input of the third trained machine learning model includes imaging parameters and/or image features of the MR images, and an output is the count of sub-models. It can be trained based on third historical data, which includes an actual count of sub-models (labels) under different imaging parameters and/or image features. These labels may be obtained through manual annotation or other methods.

In some embodiments, the second count of the target MR mappings may be less than the first count. For example, if the first count is at least 2, then the second count is at least 1, and both the first and second counts are positive integers.

In some embodiments, the second count may be determined based on one or more target quantitative parameters of the subject that is desired to be obtained based on MR scanning or user requirements, which reflects the user's imaging needs for magnetic resonance scanning.

In some embodiments, the one or more target quantitative parameters may include at least one of T1 mapping, T2 mapping, T1rho mapping, a proton density, a diffusion coefficient, a diffusion tensor, etc.

In some embodiments, the MR images may include at least one MR image whose target imaging parameter is the same as a target quantitative parameter. For example, if the one or more target quantitative parameters include T1 and T2, the first count of MR images may include at least one T1-weighted image and at least one T2-weighted image. As another example, if the one or more target quantitative parameters include T1, T2, and T1rho, the first count of MR images may include at least one T1-weighted image, at least one T2-weighted image and at least one T1rho-weighted image. In some embodiments, given that the second count is less than the first count, the MR images may include an MR image whose target imaging parameter is different from the one or more target quantitative parameters. Preferably, the MR images may include more T1-weighted images to provide more information. In some embodiments, in order to provide more information to obtain an accurate image when acquiring multiple types of MR mappings at the same time, the MR images may include one or more T1-weighted images.

In some embodiments, it is also possible to input different types of MR images simultaneously for the target mapping corresponding to one of them. For example, suppose the input quantitative parameters corresponding to the MR images include T1 and T2. In that case, the trained machine learning model can specify which MR mapping to output in several ways. For instance, the model can output the MR mapping corresponding to the target quantitative parameter of the MR image input first. If the type of target quantitative parameter corresponding to the first input MR image is T1, the model outputs the T1 mapping. If the type of target quantitative parameter corresponding to the first input MR image is T2, the model outputs the T2 mapping. Additionally, the input MR images can be labeled, specific features can be input, or model parameters can be set to make the model output the MR mapping corresponding to a specified type of target quantitative parameter. This embodiment does not limit the specific methods. In some embodiments, the processing device may input the MR images into the trained machine learning model, the trained machine learning model may process the input data and output the second count of target MR mappings.

In some embodiments, the MR images may include only one type of MR images (e.g., T1, T2, or T1rho). In this case, after inputting the MR images into the trained machine learning model, the trained machine learning model may process the input data and output the MR mapping corresponding to the type. For example, if the input is the first count of T1-weighted images, the trained machine learning model outputs the second count of T1 mappings. The first count is at least 2, and the second count is less than the first count, for example, the second count may be 1. Similarly, when the input is the first count of T2-weighted images, the trained machine learning model outputs the second count of T2 mappings.

In some embodiments, the MR images may include two or more types of weighted images (e.g., any combination of two or more of T1, T2, and T1rho). In this case, after inputting the MR images into the trained machine learning model, the trained machine learning model processes the input data and outputs multiple MR mappings corresponding to the input types. For example, if the input is the first count of T1-weighted images and T2-weighted images, the trained machine learning model outputs the second count of T1 mappings and T2 mappings. The first count is at least 2, and the second count is less than the first count, for example, the second count may be 1.

In some embodiments, each sub-model within the trained machine learning model may process the MR images, or each sub-model may separately process a portion of the MR images. Preferably, each sub-model processes the MR images.

For example, the trained machine learning model may include three sub-models (labeled 1, 2, 3), the MR images may include two T1-weighted images and one T2-weighted image, and a final output of the trained machine learning model may include one T1 mapping and one T2 mapping. The processing of the MR images by the trained machine learning model may be as follows.

Both of the two T1-weighted images and the one T2-weighted image may be inputted into each of the three sub-models. For example, the two T1-weighted images and the one T2-weighted image may be inputted into the input layer of the trained machine learning model and the input layer may input the two T1-weighted images and the one T2-weighted image into each of the three sub-models.
1) Input the two T1-weighted images and one T2-weighted image into the sub-model 1, which outputs a T1 mapping (denoted as T1_1) and a T2 mapping (denoted as T2_1).
2) Input the two T1-weighted images and one T2-weighted image into the sub-model 2, which outputs a T1 mapping (denoted as T1_2) and a T2 mapping (denoted as T2_2).
3) Input the two T1-weighted images and one T2-weighted image into the sub-model 3, which outputs a T1 mapping (denoted as T1_3) and a T2 mapping (denoted as T2_3).4) Obtain the final T1 mapping based on T1_1, T1_2, T1_3. The final T1 mapping may be obtained by averaging or weighting T1_1, T1_2, and T1_3. The weighting may be based on the weight of each sub-model in the trained machine learning model or pre-set weights. This embodiment does not impose limitations. The final T1 mapping may be represented as 11T1_1+12T1_2+13T1_3.11, 12, 13 denotes weights corresponding to the three sub-models and may be default settings of the system or set by a user.
5) Obtain the final T2 mapping based on T2_1, T2_2, T2_3. The specific process is similar to the weighting in operation 4).
6) Obtain the second count of Tx mappings, i.e., one T1 mapping and one T2 mapping.

The above example is for illustrative purposes only. In practical applications, the input data for each sub-model may be adjusted according to requirements. For example, in the above example, the sub-model 1 may process only two T1-weighted images and output a T1_1 mapping, the sub-model 2 may process one T1-weighted image and one T2-weighted image and output a T2_2 mapping, and the sub-model 3 may simultaneously process two T1-weighted images and one T2-weighted image and output a T1_3 mapping and a T2_3 mapping. Finally, based on the outputs of the three sub-models, the second count of MR mappings is obtained.

In some embodiments of the present disclosure, the trained machine learning model approach enables the simultaneous generation of T1, T2, and T1rho mapping images in a single scan, addressing the issue of prolonged scan times due to separate scans. Further more, by integrating multiple sub-models into the trained machine learning model, T1, T2, and/or T1rho mapping images may be obtained with just two or more weighted images, reducing patient breath-hold time and overcoming difficulties in acquiring accurate mapping images for many patients due to breath-hold time constraints, enhancing the precision and robustness of MRI imaging. For example, if the count of the MR images is equal to 2, each sub-model in the trained machine learning model may process the two MR images independently to generate two results and the two results may be associated (e.g., weighting and summing) to generate the final result.

On the other hand, the method disclosed in the embodiments of the present disclosure may provide T1, T2, and T1rho mapping simultaneously while collecting only three or more (e.g., five, six, etc.) shared weighted images, effectively reducing scan time and enhancing patient comfort. The trained machine learning model, utilizing combinations such as fully connected (FC) networks and three-dimensional deep convolutional neural networks (3D CNNs), leverages nonlinear relationships between MR images and between them and MR mappings. Compared to training models separately to obtain MR mapping images, this approach effectively utilizes autocorrelation and cross-correlation among MR images to improve the quality and accuracy of MR mapping imaging results.

That is to say, a trained machine learning model can output a target mapping one at a time, or it can output multiple target mappings at once, depending on the input data. For example, when the input consists of two or more MR-weighted images of the same type, the trained machine learning mode may output a corresponding MR mapping for the type of the input MR-weighted images; when the input consists of two or more types of MR-weighted images, the trained machine learning mode may output multiple types of MR mappings, and the types of the output MR mappings may correspond to the two or more MR-weighted images in the input.

The related technologies for generating an MR mapping may use a single network model to obtain a mapping image based on an input of at least three weighted images, and cannot obtain multiple different types of MR mappings at the same time. According to some embodiments of the present disclosure, the trained machine learning model may include at least two sub-models, and the sub-models may be assigned weights, so that the number of input images to the trained machine learning model is lower (minimum two weighted images), and multiple different types of MR mappings can be obtained simultaneously.

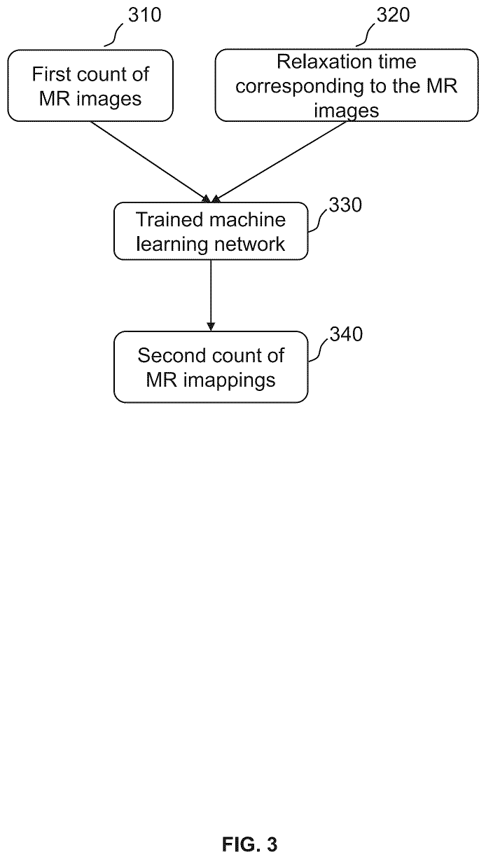

FIG. 3 is an exemplary schematic diagram illustrating the acquisition of MR mapping according to other embodiments of the present disclosure. In some embodiments, the operations illustrated in FIG. 300 may be performed by a system for MR imaging (e.g., the MRI system 100) or a processing device (e.g., the processing device 120).

In some embodiments, the processing device may be capable of obtaining the relaxation time corresponding to at least one of the MR images; and processing the MR images and the relaxation time corresponding to at least one of the MR images through the trained machine learning model to obtain the second count of MR mappings.

In the MRI, the relaxation time may be a time constant that describes the decay of nuclear magnetic resonance signals over time, including a T1 relaxation time and a T2 relaxation time.

The T1 relaxation time (also known as longitudinal relaxation time or spin-lattice relaxation time) may refer to a time constant for the longitudinal magnetization vector of nuclear magnetic resonance in an external magnetic field to return to its equilibrium state. Specifically, the T1 relaxation time may refer to a time required for the longitudinal magnetization vector to recover to 63% of its equilibrium value.

The T2 relaxation time (also known as transverse relaxation time or spin-spin relaxation time) may refer to a time constant required for the transverse magnetization vector of nuclear magnetic resonance in an external magnetic field to decay to 37% of its initial value.

The T1 relaxation time and the T2 relaxation time are very important parameters in the MRI, which may affect image contrast and signal intensity. Different tissues exhibit different signal intensities in MRI images due to differences in their T1 and T2 relaxation times, which may be configured to distinguish and diagnose various pathologies and tissue types.

In addition, the relaxation time may also include a T1rho relaxation time (also known as rotating frame longitudinal relaxation time), which refers to the relaxation time of the longitudinal magnetization vector in a rotating reference frame. It is different from the conventional T1 relaxation time and involves maintaining the processing state of the magnetization vector through continuous application of a radiofrequency field (e.g., a low-frequency B1 field) within the rotating frame. T1rho imaging may be configured to assess microscopic motion and interactions in tissues, such as in the study of cartilage, brain, heart, and liver, and the T1rho imaging plays an important role in detecting early tissue degeneration and other pathological changes.

As shown in FIG. 3, the processing device may input the first count of MR images 310 and the relaxation time corresponding to the Tx-weighted images 320 into the trained machine learning model 330. After processing the input data, the trained machine learning model 330 may output the second count of MR mappings 340.

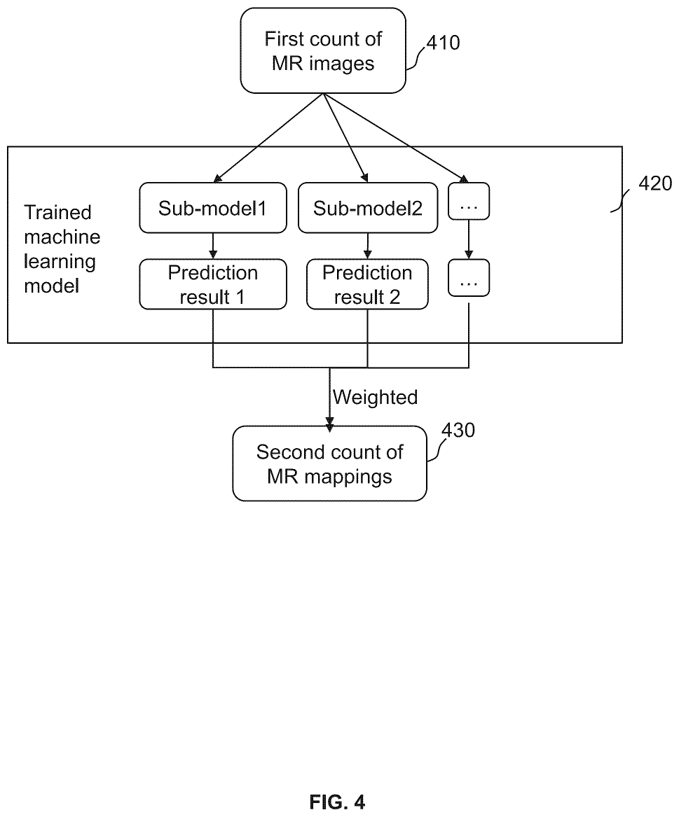

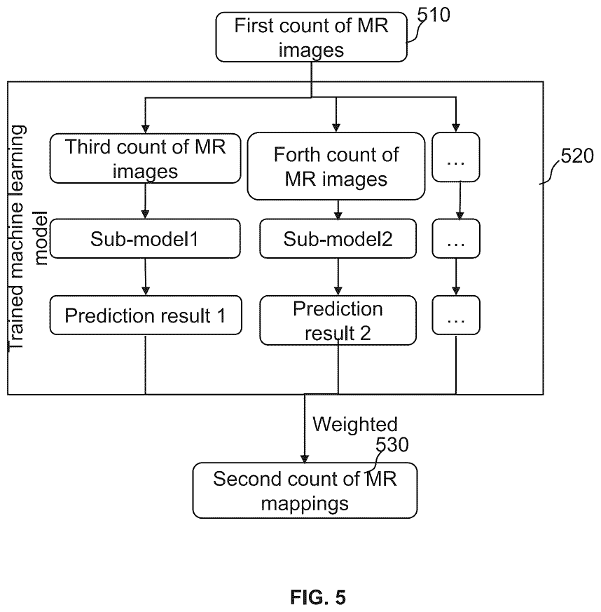

For more information about how the trained machine learning model processes the input MR images and relaxation times, please refer to the descriptions of FIGS. 4 and 5 below.

FIG. 4 is an exemplary schematic diagram illustrating the acquisition of a specific type of MR mapping according to some embodiments of the present disclosure.

In some embodiments, the obtained MR mapping may be any one of T1 mapping, T2 mapping, and T1rho mapping.

The processing device may input the MR images 410 into the trained machine learning model 420. Within the trained machine learning model, each sub-model, such as sub-model 1, sub-model 2, . . . , processes the MR images separately and generates its own output. For example, the sub-model 1 may output a prediction result 1 and the sub-model 2 may output a prediction result 2. The prediction result refers to the MR mapping predicted by the sub-model.

The processing device may weight the output results of multiple sub-models to obtain one or more target MR mappings 430. For example, the processing device may weight the prediction result 1 and the prediction result 2 to obtain a target MR mapping. As a further example, the prediction result 1 may be a first T1 mapping and the prediction result 2 may be a second T1 mapping, the processing device may determine a target T1 mapping by weighting the first T1 mapping and the second T1 mapping.

It should be noted that although FIG. 4 shows an example where each sub-model processes the MR images, in practice, each sub-model may also process a different count (less than the first count) of MR images. For specific examples, please refer to FIG. 5.

FIG. 5 is an exemplary schematic diagram illustrating the acquisition of multiple types of MR mappings according to some embodiments of the present disclosure.

In some embodiments, the multiple MR mappings obtained simultaneously may be any combination of two or more of T1 mapping, T2 mapping, and T1rho mapping. For example, they may be T1 mapping and T2 mapping, T1 mapping and T1rho mapping, or T1 mapping, T2 mapping, and T1rho mapping, etc. The types of MR mappings ultimately acquired depend on the user's image acquisition targets and the types of input MR images. Relevant descriptions can be found in the explanation of FIG. 2.

The processing device may input the MR images 510 into the trained machine learning model 520. The types of input MR images need to satisfy the corresponding relationship with the MR mappings to be acquired. For example, if the target quantitative parameters include T1 mapping and T2 mapping, the MR images may include at least one T1-weighted image and one T2-weighted image; if the target quantitative parameters include T1 mapping, T2 mapping, and T1rho mapping, the MR images may include at least one T1-weighted image, one T2-weighted image, and one T1rho-weighted image.

Within the trained machine learning model 520, each sub-model may process a different count (less than or equal to the first count) of MR images. For example, the sub-model 1 may process a first portion of MR images the sub-model 2 may process a second portion of MR images, and so on. The count of the first portion of MR images and the count of the second portion of MR images (not shown in the figure) may be the same or different and are all less than or equal to the first count.

Finally, the processing device weights the output results of multiple sub-models to obtain the second count of MR mappings 530. In the case of simultaneously obtaining multiple types of MR mappings, the second count is the total sum of the quantities of the multiple types of MR mappings. For example, if the final output is one T1 mapping, one T2 mapping, and one T1rho mapping, then the second count is 3.

It should be noted that although FIG. 4 shows an example of obtaining a certain type of MR mapping and FIG. 5 shows an example of simultaneously obtaining multiple types of MR mappings, it should be understood that the situation shown in FIG. 4 may also be used for simultaneously obtaining multiple types of MR mappings, and the situation shown in FIG. 5 may also be used for obtaining a certain type of MR mapping.

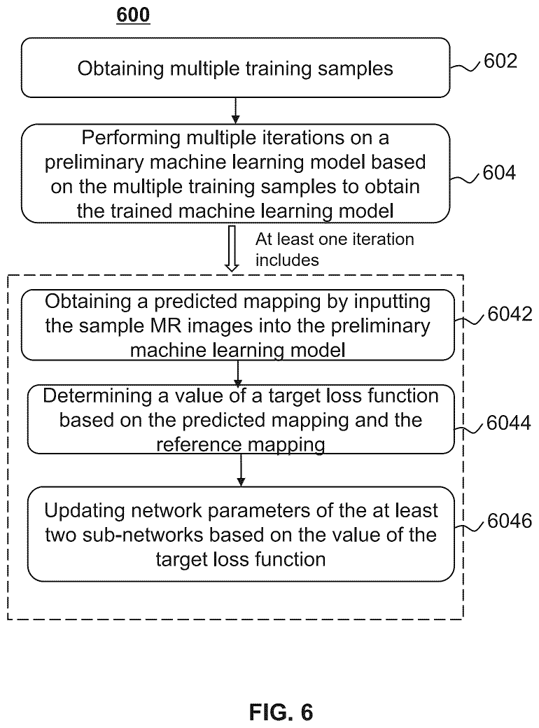

FIG. 6 is an exemplary flowchart illustrating a training process for a trained machine learning model according to some embodiments of the present disclosure. In some embodiments, process 600 may be executed by a system for MR imaging (e.g., the system 100 for MR imaging) or a processing device (e.g., the processing device 120). As shown in FIG. 6, process 600 includes the following steps.

In step 602, multiple training samples may be obtained.

In some embodiments, each training sample may include sample MR images and a reference mapping. The sample MR images refer to MR images used for model training, and the reference mapping may serve as the gold standard during model training.

The sample MR images may be obtained based on historical data, and the reference mapping may be obtained through manual determination.

In step 604, multiple iterations may be performed on a preliminary machine learning model based on the multiple training samples to obtain the trained machine learning model.

In some embodiments, the preliminary machine learning model may include at least two sub-models. The processing device may input multiple training samples into the preliminary machine learning model in batches, obtain the output of the preliminary machine learning model, and update its parameters based on the output. After multiple iterations, when an iteration stop condition is met, such as reaching a certain number of iterations or the loss function converging, the machine learning model is obtained. In some embodiments, the at least one iteration in the multiple iterations includes the following operations.

In step 6042, a predicted mapping may be obtained by inputting the sample MR images into the preliminary machine learning model.

The predicted mapping may be an output of the preliminary machine learning model after processing the input sample MR images.

In step 6044, a value of a target loss function may be determined based on the predicted mapping and the reference mapping.

In some embodiments, the target loss function may include at least two loss terms, each corresponding to a sub-model. The target loss function may be constructed based on the predicted mapping and the reference mapping. For example, if the preliminary machine learning model includes multiple sub-models, then the target loss function=first loss term+second loss term+ . . . +nth loss term.

In some embodiments, the target loss function may also include other terms, such as a regularization term, etc.

In step 6046, network parameters of the at least two sub-models may be updated based on the value of the target loss function.

The synchronous updating refers to updating the parameters of at least two sub-models in each iteration. For example, the preliminary machine learning model may include an input layer, a fully connected layer, a convolutional neural network layer, and an output layer, where the fully connected layer and the convolutional neural network layer may be regarded as sub-models respectively.

The input layer may be configured to input x (input data) into the trained machine learning model.

The fully connected layer, configured to input x passes through the FC layer to obtain the output f(x) and output f(x)=W_{fc}x+b_{fc}, where W_{fc} denotes weights of the FC layer, and b_{fc} denotes biases of the FC layer.

The convolutional neural network layer, configured to input x passes through the CNN to obtain the output g(x), where g(x)=CNN (x), and g(x) may be obtained through a series of operations such as convolution, pooling, activation functions, etc.

The output layer, configured to output of the FC layer f(x) and the weighted output of the CNN are added together to obtain the final output y, where y=f(x)+λ·g(x), and λ is the weighting parameter of the CNN, also known as the weighting factor.

In some embodiments, the weighting parameter A may be a fixed value or may be updated along with the parameters of the preliminary machine learning model. The fixed value may be obtained based on experience or directly specified by the user.

For updating the weighting parameter λ, it may be updated using the backpropagation algorithm. For example, assuming that the target loss function is represented by L, the gradient for λ may be represented by the following formula (1).

$$\frac{\partial L}{\partial λ} = \frac{\partial l}{\partial y} \cdot \frac{\partial y}{\partial λ} \qquad ( 1 )$$

where

$$\frac{\partial y}{\partial λ} = g ( x ) , so \frac{\partial L}{\partial λ} = \frac{\partial l}{\partial y} \cdot g ( x ) .$$

The value of λ may be updated based on this gradient, for example, the processing device may update the value of λ according to a gradient descent algorithm. As a further example, the update of the value of λ may include obtaining the gradient

$$\frac{\partial L}{\partial λ}$$

by taking the derivative of the loss function L, and updating the value of λ according to a update rule. The update rule may be denoted as the following formula (2):

$${λ}_{new} = {λ}_{old} - η \frac{\partial L}{\partial λ} , \qquad ( 2 )$$

where

$$\frac{\partial L}{\partial λ}$$

denotes the gradient, λ_{new} denotes the updated value of λ, λ_{old} denotes the previous value of λ before the update, η denoted the learning rate, and is used to control the step size of the update. If the gradient

$$\frac{\partial L}{\partial λ}$$

is positive, it means that the current λ is large and the value of A should be reduced; if the gradient

$$\frac{\partial L}{\partial λ}$$

is negative, it means that the current λ is small and λ should be increased.

In some embodiments, based on the value of the target loss function, updating the network parameters of at least two sub-models and the weighting parameter λ may be done synchronously.

In some embodiments, the processing device may also synchronously update the network parameters of at least two sub-models based on the value of the target loss function, and update the weighting parameter λ according to a preset frequency. Updating according to the preset frequency means updating at a certain iteration interval. For example, if the preset frequency is 1, it means updating the weighting parameter every time the network parameters of the sub-models are updated; if the preset frequency is 2, it means updating the weighting parameter once every two updates of the network parameters of the sub-models.

In some embodiments, the preset frequency may be determined based on the imaging parameters and the image features of the MR images. If the resolution of the image in the imaging parameters is higher, the motion artifacts in the image features are larger, and the signal-to-noise ratio is lower, the preset frequency value may be smaller (with a minimum of 1). The image features may refer to the features of multiple images, such as the average image features of multiple historical MR images.

In some embodiments, the preset frequency may also be determined based on a vector database. For example, the vector database is constructed, which includes multiple reference vectors (the imaging parameters, the image features of MR images) and corresponding reference preset frequencies (constructed based on historical actual preset frequencies). During application, the processing device may construct a target feature vector based on the current imaging parameters and image features of the MR image, match at least one reference vector satisfying a preset condition in the vector database based on the target feature vector, and calculate the average value based on the preset frequencies corresponding to the reference vectors satisfying the preset conditions, which is used as the preset frequency.

In some embodiments, the processing device may also determine the preset frequency through a frequency determination model. Based on the complexity of imaging parameters and image features, the frequency determination model may adopt deep learning models such as the CNN combined with the RNN or the LSTM network. An input of the frequency determination model includes the imaging parameters and the image features of the MR images, and an output is the preset frequency.

For more information about the training of the vector database and the frequency determination model, please refer to similar content in FIG. 2. The difference lies in the data configured to construct the vector database, the input and output of the model, while other aspects (such as model training) may be mutually referenced.

It should be noted that the above descriptions of various processes are merely for example and illustration, and do not limit the scope of application of the present disclosure. For those skilled in the art, various modifications and changes can be made to the processes under the guidance of the present disclosure. However, these modifications and changes are still within the scope of the present disclosure. For example, adding storage steps to various processes.

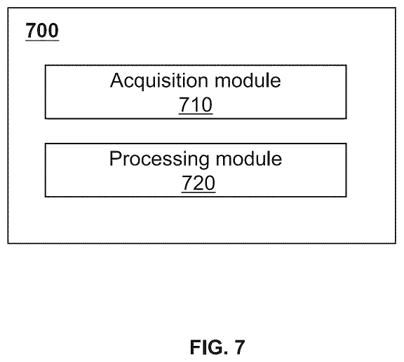

FIG. 7 is an exemplary block diagram illustrating a system for MR imaging according to some embodiments of the present disclosure. As shown in FIG. 7, the system 700 may include an acquisition module 710 and a processing module 720.

The acquisition module 710 may be configured to obtain MR images of a subject, each of the MR images being acquired by an MRI scanner according to a target imaging parameter, at least two of the MR images corresponding to different target imaging parameters.

The processing module 720 may be configured to obtain MR mappings corresponding to at least a portion of the MR images by processing the MR images through a trained machine learning network, a second count of the MR mappings being less than the first count of the MR images. The trained machine learning network may include at least two sub-models, and each sub-model processes at least one MR image.

The basic concepts have been described above, apparently, in detail, as will be described above, and does not constitute limitations of the disclosure. Although there is no clear explanation here, those skilled in the art may make various modifications, improvements, and modifications of present disclosure. This type of modification, improvement, and corrections are recommended in present disclosure, so the modification, improvement, and the amendment remain in the spirit and scope of the exemplary embodiment of the present disclosure.

At the same time, present disclosure uses specific words to describe the embodiments of the present disclosure. As “one embodiment”, “an embodiment”, and/or “some embodiments” means a certain feature, structure, or characteristic of at least one embodiment of the present disclosure. Therefore, it is emphasized and should be appreciated that two or more references to “an embodiment” or “one embodiment” or “an alternative embodiment” in various parts of present disclosure are not necessarily all referring to the same embodiment. Further, certain features, structures, or features of one or more embodiments of the present disclosure may be combined.

In addition, unless clearly stated in the claims, the order of processing elements and sequences, the use of numbers and letters, or the use of other names in the present disclosure are not used to limit the order of the procedures and methods of the present disclosure. Although the above disclosure discusses through various examples what is currently considered to be a variety of useful embodiments of the disclosure, it is to be understood that such detail is solely for that purpose, and that the appended claims are not limited to the disclosed embodiments, but, on the contrary, are intended to cover modifications and equivalent arrangements that are within the spirit and scope of the disclosed embodiments. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. However, this disclosure does not mean that the present disclosure object requires more features than the features mentioned in the claims. Rather, claimed subject matter may lie in less than all features of a single foregoing disclosed embodiment.

In some embodiments, the numbers expressing quantities of ingredients, properties, and so forth, used to describe and claim certain embodiments of the application are to be understood as being modified in some instances by the term “about,” “approximate,” or “substantially”. Unless otherwise stated, “about,” “approximate,” or “substantially” may indicate ±20% variation of the value it describes. Accordingly, in some embodiments, the numerical parameters used in the specification and claims are approximate values, and the approximation may change according to the characteristics required by the individual embodiments. In some embodiments, the numerical parameter should consider the prescribed effective digits and adopt a general digit retention method. Although in some embodiments, the numerical fields and parameters used to confirm the breadth of its range are approximate values, in specific embodiments, such numerical values are set as accurately as possible within the feasible range.

With respect to each patent, patent application, patent application disclosure, and other material cited in the present disclosure, such as articles, books, manuals, publications, documents, etc., the entire contents thereof are hereby incorporated by reference into the present disclosure. Application history documents that are inconsistent with the contents of the present disclosure or that create conflicts are excluded, as are documents (currently or hereafter appended to the present disclosure) that limit the broadest scope of the claims of the present disclosure. It should be noted that in the event of any inconsistency or conflict between the descriptions, definitions, and/or use of terms in the materials appended to the present disclosure and those described in the present disclosure, the descriptions, definitions, and/or use of terms in the present disclosure shall prevail.

At last, it should be understood that the embodiments described in the present disclosure are merely illustrative of the principles of the embodiments of the present disclosure. Other modifications that may be employed may be within the scope of the present disclosure. Thus, by way of example, but not of limitation, alternative configurations of the embodiments of the present disclosure may be utilized in accordance with the teachings herein. Accordingly, embodiments of the present disclosure are not limited to that precisely as shown and described.

What is claimed is:

1. A method implemented on a computing device including at least one processor and a storage device, the method, comprising:
obtaining magnetic resonance (MR) images of a subject;
obtaining one or more target MR mappings corresponding to at least a portion of the MR images by processing the MR images through a trained machine learning model, a second count of the target MR mappings being less than a first count of the MR images;
wherein the trained machine learning model includes at least two sub-models, and each sub-model processes at least one of the MR images.

2. The method of claim 1, wherein the obtaining one or more target MR mappings corresponding to at least a portion of the MR images by processing the MR images through a trained machine learning model includes:
obtaining a relaxation time corresponding to at least one of the MR images; and
obtaining the one or more target MR mappings by processing the MR images and the relaxation time corresponding to the at least one of the MR images through the trained machine learning model.

3. The method of claim 1, wherein the first count is determined based on the second count.

4. The method of claim 1, further comprising:
determining the second count based on one or more target quantitative parameters of the subject, each of the one or more target MR mappings corresponding to one of the one or more target quantitative parameters.

5. The method of claim 4, wherein the MR images include at least one MR image, a type of a target imaging parameter corresponding to the at least one MR image being the same as a type of one of the one or more target quantitative parameters.

6. The method of claim 1, wherein one of the sub-models includes at least one of a fully connected (FC) network, a convolutional neural network (CNN), a recurrent neural network (RNN), or a Transformer.

7. The method of claim 1, wherein the trained machine learning model is obtained through operations including:
obtaining multiple training samples, wherein each training sample of the multiple training samples includes sample MR images and a reference mapping;
performing multiple iterations on a preliminary machine learning model based on the multiple training samples to obtain the trained machine learning model; the preliminary machine learning model including at least two sub-models.

8. The method of claim 7, wherein at least one iteration of the multiple iteration includes:
obtaining a predicted mapping by inputting the sample MR images into the preliminary machine learning model;
determining a value of a target loss function based on the predicted mapping and the reference mapping; and
updating network parameters of the at least two sub-models based on the value of the target loss function.

9. The method of claim 7, wherein the target loss function includes at least two loss terms, and each loss term corresponds to a sub-model.

10. The method of claim 9, wherein at least one of the at least two loss terms includes a weighting factor, the weighting factor being updated when updating network parameters of the at least two sub-models.

11. The method of claim 1, wherein the obtaining the one or more target mappings corresponding to at least a portion of the MR images by processing of the MR images through a trained machine learning network includes:
obtaining a first MR mapping corresponding to a target quantitative parameter by processing a first portion of the MR images through a first sub-model;
obtaining a second MR mapping corresponding to the target quantitative parameter by processing a second portion of the MR images through a second sub-model;
based on weight parameters of the first sub-model and the second sub-model, obtaining a target MR mapping corresponding to the target quantitative parameter by weighting the first MR mapping and the second MR mapping.

12. The method of claim 1, wherein the obtaining the one or more target mappings corresponding to at least a portion of the MR images by processing of the MR images through a trained machine learning network includes:
obtaining a first MR mapping corresponding to a target quantitative parameter by processing the MR images through a first sub-model;
obtaining a second MR mapping corresponding to the target quantitative parameter by processing the MR images through a second sub-model;
based on weight parameters of the first sub-model and the second sub-model, obtaining a target MR mapping corresponding to the target quantitative parameter by weighting the first MR mapping and the second MR mapping.

13. The method of claim 1, wherein the first count is equal to 2, and the MR images includes a first MR image corresponding to a first target imaging parameter and a second MR image corresponding to a second target imaging parameter, the one or more target MR mappings corresponding to a target quantitative parameter whose type is same as a type of the first target imaging parameter or the second target imaging parameter.

14. The method of claim 1, wherein the MR images are acquired in one single scan, and the one or more target MR mappings include at least one of a T1 mapping, a T2 mapping, or a T1rho mapping.

15. The method of claim 1, wherein the MR images are acquired in one single scan, and the one or more target MR mappings include one of a T1 mapping, a T2 mapping, and a T1rho mapping.

16. The method of claim 1, wherein obtaining one or more target MR mappings corresponding to at least a portion of the MR images by processing the MR images through a trained machine learning model includes:
inputting T1-weighted MR images acquired in one single scan corresponding to each of the T1 weighted MR images into the trained machine learning model; and
generating a T1 mapping by the trained machine learning model.

17. The method of claim 1, wherein obtaining one or more target MR mappings corresponding to at least a portion of the MR images by processing the MR images through a trained machine learning model includes:
inputting T2-weighted MR images acquired in one single scan corresponding to each of the T2-weighted MR images into the trained machine learning model; and
generating a T2 mapping by the trained machine learning model.

18. The method of claim 1, wherein obtaining one or more target MR mappings corresponding to at least a portion of the MR images by processing the MR images through a trained machine learning model includes:
inputting T1rho-weighted MR images acquired in one single scan corresponding to each of the T1rho-weighted MR images into the trained machine learning model; and
generating a T1rho mapping by the trained machine learning model.

19. A system for magnetic resonance imaging, comprising:
at least one processor and at least one storage, wherein
the at least one storage is configured to store computer instructions; and
the at least one processor is configured to execute at least a portion of the computer instructions to:
obtaining magnetic resonance (MR) images of a subject, at least two of the MR images being acquired by an MRI scanner according to different imaging parameters;
obtaining one or more target MR mappings corresponding to at least a portion of the MR images by processing the MR images through a trained machine learning model, a second count of the target MR mappings being less than a first count of the MR images;
wherein the trained machine learning model includes at least two sub-models, and each sub-model processes at least one of the MR images.

20. A computer-readable storage medium storing computer instructions, wherein when reading the computer instructions in the storage medium, the computer performs a method including:
obtaining magnetic resonance (MR) images of a subject, at least two of the MR images being acquired by an MRI scanner according to different imaging parameters;
obtaining one or more target MR mappings corresponding to at least a portion of the MR images by processing the MR images through a trained machine learning model, a second count of the target MR mappings being less than a first count of the MR images;
wherein the trained machine learning model includes at least two sub-models, and each sub-model processes at least one of the MR images.
